(19) United States
(12) Patent Application Publication
(10) Pub. No.: US 2007/0026697 A1
(43) Pub. Date: Feb. 1, 2007

(54) Interface card with a control chip

(75) Inventors: Ming-Lien Hsu, Taipei City (TW); Chien-Lung Chang, Taipei City (TW); Shi-Ru Wang, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/492,852

(22) Filed: Jul. 26, 2006

(30) Foreign Application Priority Data
Jul. 27, 2005 (TW) 094125457

(51) Int. Cl. H05K 1/00

(52) U.S. Cl. 439/61

(57) ABSTRACT

An interface card includes a bracket, a circuit board including a first side and a second side, at least one connector connected to the bracket and the first side of the circuit board, and a control chip positioned on the second side of the circuit board.

### BACKGROUND OF THE INVENTION

1. Field of the Invention

The present invention relates to an interface card with a control chip located on a side opposite to a side where a connector is located, and more particularly, to a display card with a graphics processing unit located on a side opposite to a side where a connector is located.

2. Description of the Prior Art

In modern information society, computer systems are becoming necessities, such as desktops, notebook computers, servers, and so on. The operation speed of computers is getting faster and faster so that the computer is becoming powerful and is utilized in a wide variety of fields. Therefore, components of the computer generate more heat when processing operations than before. If the heat generated by the components of the computer cannot be dissipated effectively, the stability and operation speed of the computer will be reduced.

Please refer to FIG. 1. FIG. 1 is a diagram of a display card 10 inserting into a motherboard 12 according to the prior art. The motherboard 12 includes a plurality of slots 14 which can conform to a standard of Peripheral Component Interface-Express (PCI-E), Peripheral Component Interface (PCI), and so on. A plurality of interface cards 16 is inserted into the slots 14. The interface card 16 can be a sound card, a SCSI card, a network card, and so on. The motherboard 12 further includes a display slot 18 which can conform to a standard of Peripheral Component Interface-Express, Peripheral Component Interface, Accelerated Graphics Port interface, and so on, and the display card 10 is inserted into the display slot 18 for processing image signals.

Please refer to FIG. 1, FIG. 2, and FIG. 3. FIG. 2 is a front view of the display card 10 shown in FIG. 1 according to the prior art. FIG. 3 is a back view of the display card 10 shown in FIG. 1 according to the prior art. The display card 10 includes a circuit board 20 which can be a printed circuit board, and a bracket 22 connected to the circuit board 20 for wedging in an opening of a casing (not shown in figures). The bracket 22 can be an L-shaped bracket. A plurality of connectors 24 is positioned on the bracket 22 for outputting or receiving image signals. The connectors 24 are positioned on the front side A1 of the circuit board 20 of the display card 10, wherein the front side A1 is a front side of the circuit board 20 when the bracket 22 is on the left of the circuit board 20, and a back side A2 is a front side of the circuit board 20 when the bracket 22 is on the right of the circuit board 20. The display card 10 further includes a graphics processing unit 26 installed on the front side A1 of the circuit board 20 for controlling operation of the display card 10, and golden fingers 28 for inserting in the display slot 18 of the motherboard 12. The golden fingers 28 can conform to a standard of Peripheral Component Interface-Express (PCI-E), Peripheral Component Interface (PCI), Accelerated Graphics Port interface, and so on. The interface of the golden fingers 28 needs to match the interface of the display slot 18. The golden fingers 28 include a front side 28a and a back side 28b defined according to the specification of the golden fingers 28, such as PCI, PCI-E, AGP, and so on. The front side 28a of the golden fingers 28 and the front side A1 of the circuit board 20 are located on the same side, and the back side 28b of the golden fingers 28 and the back side A2 of the circuit board 20 are located on the same side. The display card 10 further includes a plurality of video memories 30 installed on the circuit board 20. The video memories 30 can be installed on the front side A1 or the back side A2 of the circuit board 20.

As shown in FIG. 1, conventionally the graphics processing unit 26 is positioned on the front side A1 of the circuit board 20, that is, on the same side as the front side 28a of the golden fingers 28. Hence the graphics processing unit 26 is located between the circuit board 20 and a neighboring interface card 16. Especially for a motherboard of ATX specification, the front side A1 of the circuit board 20 of the display card 10 is close to the neighboring interface card 16. When the graphics processing unit 26 processes complicated operations, such as 3D image processing, so as to generate lots of heat, the heat cannot be dissipated easily due to the narrow space between the display card 10 and the neighboring interface card 16 because of the short gap between the slot 14 of the motherboard 12 and the display slot 18, so that the temperature of the display card 20 will increase and the stability of the computer and the service life of the display card 10 will be reduced.

For solving the heat-dissipating problem of the graphics processing unit 26 of the display card 10, a fan can be installed on the display card 10 and a heat pipe can be applied to transmit heat generated by the graphics processing unit 26 to a heat sink (not shown in figures) positioned on the back side A2 of the circuit board 20. But the above-mentioned solutions can not solve the heat-dissipating problem effectively and the cost of the display card 10 will increase.

### SUMMARY OF THE INVENTION

It is therefore a primary objective of the claimed invention to provide an interface card with a control chip located on a side opposite to a side where a connector is located for solving the above-mentioned problem.

According to claimed invention, an interface card includes a bracket, a circuit board including a first side and a second side, at least one connector connected to the bracket and the first side of the circuit board, and a control chip positioned on the second side of the circuit board.

According to claimed invention, an interface card includes a bracket, and a circuit board including a first side and a second side wherein the circuit board is fixed on the right of the bracket, golden fingers are positioned on the bottom of the circuit board, and the first side is a front side of the circuit board when the bracket is on the left of the circuit board. The interface card further includes a control chip positioned on the second side of the circuit board.

According to claimed invention, an electronic appliance includes a motherboard including a plurality of slots, and at least one interface card including a bracket, and a circuit board including a first side and a second side wherein the circuit board is fixed on the right of the bracket, golden fingers are positioned on the bottom of the circuit board, and the first side is a front side of the circuit board when the bracket is on the left of the circuit board. The interface card further includes a control chip positioned on the second side of the circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a display card inserting into a motherboard according to the prior art.

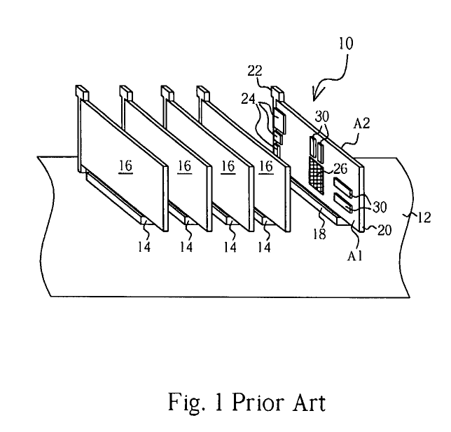

FIG. 2 is a front view of the display card shown in FIG. 1 according to the prior art.

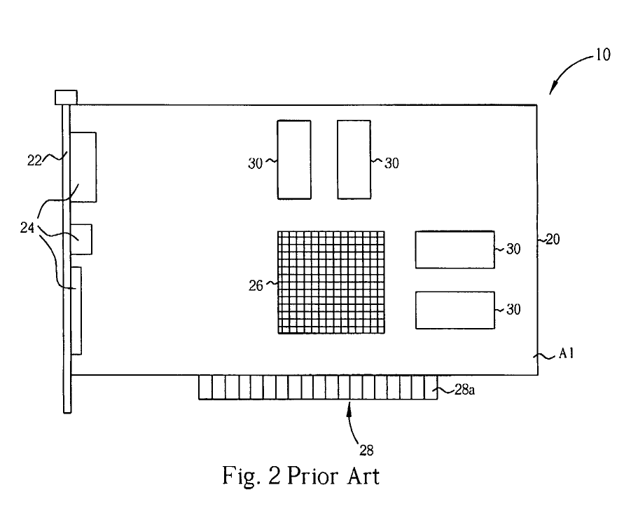

FIG. 3 is a back view of the display card shown in FIG. 1 according to the prior art.

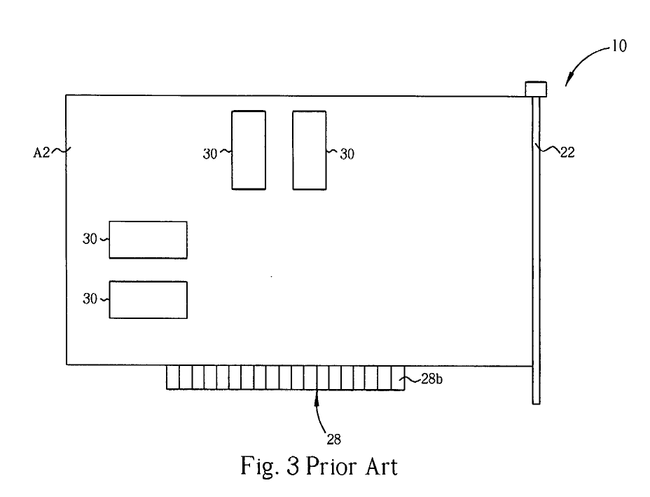

FIG. 4 is a diagram of a display card of an electronic appliance inserting into a motherboard according to the present invention.

FIG. 5 is a front view of the display card shown in FIG. 4 according to the present invention.

FIG. 6 is a back view of the display card shown in FIG. 4 according to the present invention.

### DETAILED DESCRIPTION

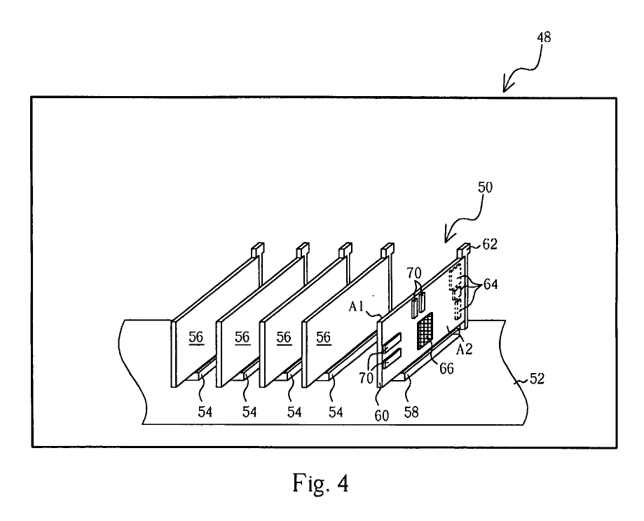

Please refer to FIG. 4. FIG. 4 is a diagram of a display card 50 of an electronic appliance 48 inserting into a motherboard 52 according to the present invention. The motherboard 52 includes a plurality of slots 54 which can conform to a standard of Peripheral Component Interface-Express (PCI-E), Peripheral Component Interface (PCI), and so on. A plurality of interface cards 56 is inserted into the slots 54. The interface card 56 can be a sound card, a SCSI card, a network card, and so on. The motherboard 52 further includes a display slot 58 which can conform to a standard of Peripheral Component Interface-Express, Peripheral Component Interface, Accelerated Graphics Port interface, and so on, and the display card 50 inserts in the display slot 58 for processing image signals.

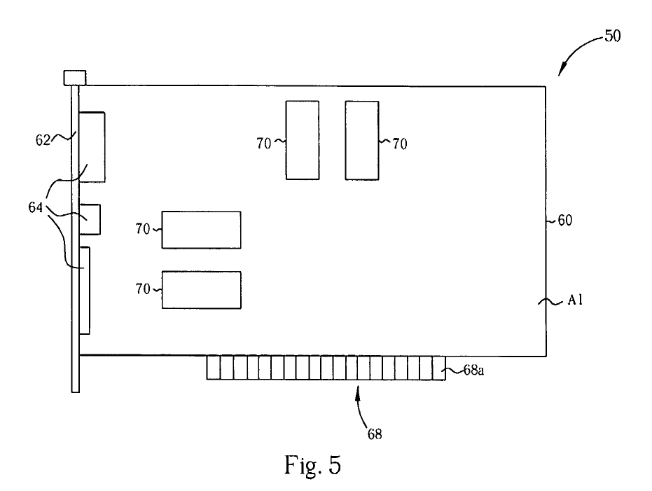

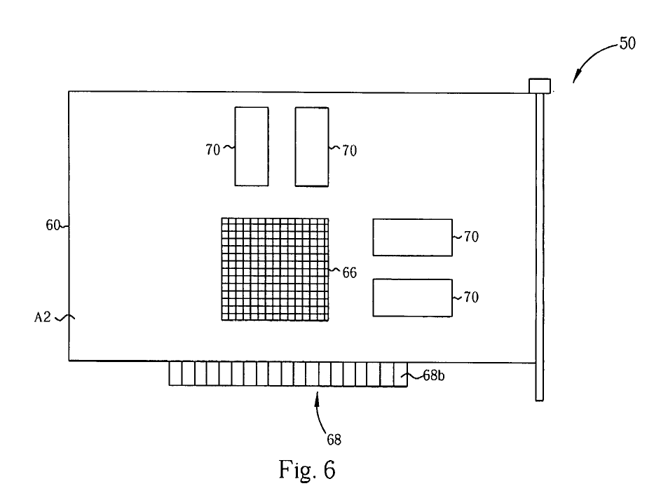

Please refer to FIG. 4, FIG. 5, and FIG. 6. FIG. 5 is a front view of the display card 50 shown in FIG. 4 according to the present invention. FIG. 6 is a back view of the display card 50 shown in FIG. 4 according to the present invention. The display card 50 includes a circuit board 60 which can be a printed circuit board, and a bracket 62 connected to the circuit board 60 for wedging in an opening of a casing (not shown in figures). The bracket 62 can be an L-shaped bracket. A plurality of connectors 64 is positioned on the bracket 62 for outputting or receiving image signals. The connectors 64 are positioned on the front side A1 of the circuit board 60 of the display card 50 wherein the front side A1 is a front side of the circuit board 60 when the bracket 62 is on the left of the circuit board 60, and a back side A2 is a front side of the circuit board 60 when the bracket 62 is on the right of the circuit board 60. The display card 50 further includes a graphics processing unit 66 installed on the back side A2 of the circuit board 60 for controlling operation of the display card 50, and golden fingers 68 for inserting in the display slot 58 of the motherboard 52. The golden fingers 68 can conform to a standard of Peripheral Component Interface-Express (PCI-E), Peripheral Component Interface (PCI), Accelerated Graphics Port interface, and so on. The interface of the golden fingers 68 needs to match the interface of the display slot 58. The golden fingers 68 includes a front side 68a and a back side 68b defined according to the specification of the golden fingers 68, such as PCI, PCI-E, AGP, and so on. The front side 68a of the golden fingers 68 and the front side A1 of the circuit board 60 are located on the same side, and the back side 68b of the golden fingers 68 and the back side A2 of the circuit board 60 are located on the same side. The display card 50 further includes a plurality of video memories 70 installed on the circuit board 60. The video memories 70 can be installed on the front side A1 or the back side A2 of the circuit board 60.

The graphics processing unit 66 is positioned on the back side A2 of the circuit board 60, that is, on the same side as the back side 68b of the golden fingers 68 instead of being located between the circuit board 60 and a neighboring interface card 60. Especially for a motherboard of ATX specification, the front side A1 of the circuit board 60 of the display card 50 is close to the neighboring interface card 56 and the back side A2 of the circuit board 60 of the display card 50 is not close to any interface card so that there is enough space for dissipating heat. That is, because the graphics processing unit 66 is positioned on the back side A2 of the circuit board 60, the heat generated by the graphics processing unit 66 can be dissipated effectively instead of being blocked by other interface card 56.

Besides the above-mentioned embodiment, the present invention discloses that a control chip can be installed on the back side of the interface card, such as a sound card, a SCSI card, a network card, and so on.

In contrast to the conventional display card, the graphics processing unit of the display card according to the present invention is installed on the back side of the display card so that there is enough space for dissipating heat generated by the graphics processing unit instead of being blocked by other interface card. Therefore, heat generated by components of the computer can be dissipated effectively so that the stability of the computer and the service life of the display card will increase. Additionally, the present invention does not need to utilize additional thermal modules for dissipating heat generated by the graphics processing unit so that the cost of the display card can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An interface card comprising:
a bracket;
a circuit board comprising a first side and a second side;
at least one connector connected to the bracket and the first side of the circuit board; and
a control chip positioned on the second side of the circuit board.

2. The interface card of claim 1 wherein the circuit board is a printed circuit board.

3. The interface card of claim 1 wherein the bracket is an L-shaped bracket.

4. The interface card of claim 1 wherein the control chip is a graphics processing unit.

5. The interface card of claim 1 wherein the circuit board comprises golden fingers for wedging into a slot of a motherboard.

6. The interface card of claim 5 wherein the golden fingers conform to a standard of Peripheral Component Interface-Express (PCI-E), Peripheral Component Interface (PCI), or Accelerated Graphics Port interface.

7. An interface card comprising:
a bracket;
a circuit board comprising a first side and a second side wherein the circuit board is fixed on the right of the bracket and golden fingers are positioned on the bottom of the circuit board and the first side is a front side of the circuit board when the bracket is on the left of the circuit board; and
a control chip positioned on the second side of the circuit board.

8. The interface card of claim 7 wherein the circuit board is a printed circuit board.

9. The interface card of claim 7 wherein the bracket is an L-shaped bracket.

10. The interface card of claim 7 wherein the golden fingers conform to a standard of Peripheral Component Interface-Express (PCI-E), Peripheral Component Interface (PCI), or Accelerated Graphics Port interface.

11. The interface card of claim 7 wherein the control chip is a graphics processing unit.

12. An electronic appliance comprising:
a motherboard comprising a plurality of slots; and
at least one interface card comprising:
a bracket;
a circuit board comprising a first side and a second side wherein the circuit board is fixed on the right of the bracket and golden fingers are positioned on the bottom of the circuit board and the first side is a front side of the circuit board when the bracket is on the left of the circuit board; and
a control chip positioned on the second side of the circuit board.

13. The electronic appliance of claim 12 wherein the circuit board is a printed circuit board.

14. The electronic appliance of claim 12 wherein the bracket is an L-shaped bracket.

15. The electronic appliance of claim 12 wherein the golden fingers conform to a standard of Peripheral Component Interface-Express (PCI-E), Peripheral Component Interface (PCI), or Accelerated Graphics Port interface.

16. The electronic appliance of claim 12 wherein the interface card is a display card and the control chip is a graphics processing unit.

17. The electronic appliance of claim 12 being a computer.
